(19) United States
(12) Patent Application Publication
(10) Pub. No.: US 2016/0025958 A1
(43) Pub. Date: Jan. 28, 2016

(54) HORSESHOE MAGNET FOR A BIOSENSOR

(71) Applicant: KONINKLIJKE PHILIPS N.V., Eindhoven (NL)

(72) Inventors: Jorrit Ernst DE VRIES, CULEMBORG (NL); Toon Hendrik EVERS, EINDHOVEN (NL); Joannes Baptist Adrianus D. VAN ZON, WAALRE (NL); Hendrikus Antonis Cornelus COMPEN, BUDEL (NL)

(73) Assignee: KONINKLIJKE PHILIPS N.V., Eindhoven (NL)

(21) Appl. No.: 14/773,455

(22) PCT Filed: Mar. 5, 2014
(86) PCT No.: PCT/IB2014/059447

§ 371 Date: Sep. 8, 2015

Related U.S. Application Data
(60) Provisional application No. 61/776,996, filed on Mar. 12, 2013.

(51) Int. Cl. G02B 21/32; H01F 7/20; G02B 21/02; G01R 33/12; G02B 21/26

(52) U.S. Cl. CPC G02B 21/32; G01R 33/1269; G02B 21/26; G02B 21/02; H01F 7/20

(57) ABSTRACT

The invention relates to a horseshoe magnet (110) that can cost -effectively be manufactured. In one embodiment, the magnet (110) comprises a yoke (120) and at least one pole tip (130) that is attached to an arm (122) of the yoke (120) but that is not integral with said arm. Optionally, the yoke (120) and the pole tip (130) are made from different materials, particularly from iron and cobalt-iron, respectively.

### FIELD OF THE INVENTION

The invention relates to a horseshoe magnet, to a sensor apparatus comprising a horseshoe magnet, and to a method for manufacturing a horseshoe magnet.

### BACKGROUND OF THE INVENTION

The WO 2011/036634 A1 discloses a biosensor apparatus in which a cartridge with a sample can be investigated. A particular magnet assembly comprising at least two magnetic subunits separated by a gap is used to generate a magnetic field in the cartridge while simultaneously allowing for an optical monitoring with the help of a microscope objective.

### SUMMARY OF THE INVENTION

It would be advantageous to provide means that allow for a cost-effective generation of a magnetic field, particularly in a cartridge of a biosensor apparatus.

This object is addressed by a horseshoe magnet according to claim 1, an apparatus according to claim 10, a method according to claim 12, and a use according to claim 15. Preferred embodiments are disclosed in the dependent claims.

According to a first aspect, the objective mentioned above is addressed by a horseshoe magnet with (at least) two pole tips that comprises the following components:
A yoke with at least one arm.
A pole tip that is attached to said arm of the yoke but that is not integral with said arm.
At least one coil.

According to a related second aspect, the objective mentioned above is addressed by a horseshoe magnet with (at least) two pole tips that comprises the following components:
A yoke with a cross-beam and at least one arm.
A pole tip that is attached to said arm of the yoke, wherein the arm is not integral with said pole tip and/or wherein the arm is not integral with the cross-beam.
At least one coil.

With other words, at least one arm of the yoke of the horseshoe magnet is:
(a) attached to but not integral to the cross-beam of the yoke while being attached to and integral with the associated pole tip;
(b) attached to and integral with the cross-beam of the yoke while being attached to but not integral with the associated pole tip;
(c) attached to but not integral to the cross-beam of the yoke and attached to but not integral with the associated pole tip.

The following explanations are valid for each of these three alternatives, even if they are described in detail only for one or two of them.

In this context, the term “horseshoe magnet” shall generally refer to a magnet assembly comprising at least two magnetic subunits, called “pole tips”, that are separated by a gap. The horseshoe magnet can particularly be designed for a use in a sensor apparatus like the biosensor described in the WO 2011/036634 A1, which is incorporated into the present application by reference.

The yoke of the horseshoe magnet will typically be U-shaped with two arms extending parallel to each other and being connected by the cross-beam, wherein a pole tip is disposed at the distal end of each arm.

The feature that the pole tip shall not be “integral” with the associated arm of the yoke or that the arm shall not be “integral” with the cross-beam means that arm and pole tip or cross-beam, respectively, are not single-piece, i.e. not monolithic. Hence they do not consist of a uniform piece of material on an atomic or molecular level (such as a piece of metal that is cast from a single molten mass).

The yoke and the pole tip and/or the cross-beam and the arm (with or without pole tip) of the described horseshoe magnet can be prefabricated separately because they are not integral. This has considerable advantages in terms of production effort and cost, particularly in case of a horseshoe magnet with a specialized shape as it is needed for example in a biosensor apparatus. The horseshoe magnet needs not be manufactured from a single block of thick material but can be manufactured from a thinner block of material, which minimizes the amount of waste material, particularly if the magnet has a complicated three-dimensional shape. Moreover, the best individual manufacturing method can be used for the production of the yoke and the pole tip, respectively, or the cross-beam and the arm (with or without pole tip), respectively.

The above disclosure comprises the case that the horseshoe magnet has just a single pole tip that is not integral with the arm of the yoke to which it is attached. Preferably, all pole tips of the horseshoe magnet are designed in this way, i.e. they are attached to an associated arm of the yoke but not integral with said arm. Explanations that are given in the following for “the pole tip” or “the arm” which are attached to each other are therefore valid for each pole tip or arm of this kind.

Similarly, the above disclosure comprises the case that the horseshoe magnet has just a single arm that is not integral with the cross-beam of the yoke to which it is attached. Preferably, all arms of the horseshoe magnet are then designed in this way, i.e. they are attached to the associated cross-beam of the yoke but not integral with said cross-beam.

Explanations that are given in the following for “the arm” are therefore valid for each arm of this kind.

The coil usually winds around an arm of the yoke. Again, there will typically be one coil around each arm of the yoke. Furthermore, the geometry of the horseshoe magnet will preferably be (mirror-)symmetric with respect to a plane lying between the two pole tips.

The coil of the horseshoe magnet generates a magnetic field when it is supplied with an electrical current. In order to guide or shape this magnetic field in a desired way, the yoke and/or the pole tip(s) of the horseshoe magnet will preferably comprise or consist of a magnetizable material. This may particularly be a ferromagnetic material like iron, cobalt, or nickel or alloys thereof.

The initially separate (i.e. not integral) parts of the horseshoe magnet may optionally have at least one of the following features:
they consist of different materials;
they are manufactured by different methods;
they are cylindrical;
they are attached to each other by screwing, clamping, and/or material bond.

In particular, the pole tip and the yoke may optionally consist of different materials. Additionally or alternatively, the arm and the cross-beam and/or the arm and the pole tip may consist of different materials. Thus the optimal material with respect to its technical function but also with respect to costs can be chosen separately for the yoke and the pole tip and/or the arm and the cross-beam and/or the arm and the pole tip. The yoke may for example be produced from iron while the pole tip is made from a (more expensive) cobalt-iron alloy.

Though the aforementioned construction of the horseshoe magnet with different materials (e.g. for the yoke and the pole tip) is possible, a preferred simple and cost effective design is achieved if the yoke and the pole tip consist of the same material, particularly of iron.

There are several possibilities how the pole tip and the yoke and/or the arm and the cross-beam can be attached to each other. The pole tip and/or the cross-beam can for example be screwed on the arm of the yoke thus allowing for a later disassembling. Additionally or alternatively, the arm may be attached to the pole tip and/or the cross-beam by material bond, for example by gluing, welding, or soldering. In still another embodiment, the arm may be attached to the pole tip and/or the cross-beam by clamping, for example by clamping to the arm that is spring loaded.

In a preferred embodiment, a mounting block may be disposed between two arms of the yoke such that it presses the pole tip against the associated arm of the yoke (or both pole tips against their associated arms, if both pole tips are non-integrally attached to the yoke). Thus the pole tip can be arranged at a well defined position with respect to the yoke, and the mounting block can further be used for the attachment of other components, too. The pressing force may be generated in this embodiment by a resiliency of the arm(s). The mounting block will typically be produced from a non-magnetic material, for example from aluminum, so that it does not affect the magnetic field generated by the horseshoe magnet.

The yoke, its cross-beam, its at least one arm, and/or the pole tip may preferably be cylindrical in order to allow for a simplified manufacturing. In this context, the term “cylindrical” is used in its broad mathematical sense, i.e. referring to a body that has a congruent top surface and bottom surface which are connected by a surface consisting of parallel lines. If the top and bottom surface are for example disks, a circular cylinder in the narrower sense of the word is achieved. A cylinder in the broad sense of the word, as it is applied here, is sometimes also called an “extruded body”.

The coil may be directly wound around the corresponding arm of the yoke. In a preferred embodiment, the design of the yoke and of the attached pole tip is however such that the coil fits over the arm of the yoke when the pole tip is not attached thereto and/or when the arm is not attached to the cross-beam. This allows for a prefabrication of the coil and the later arrangement of this prefabricated, i.e. already wound coil on the arm of the yoke, to which the pole tip or cross-beam can thereafter be connected. Thus the often sensitive and fragile mechanics of the pole tip is protected from damage during winding of the coil.

The horseshoe magnet may optionally further comprise at least one lens that is mounted between two arms of the yoke and/or between two pole tips of the yoke. The lens allows for an optical interaction with a sample adjacent to the pole tips, wherein said sample can simultaneously be reached by the magnetic field generated by the horseshoe magnet.

The horseshoe magnet may preferably comprise a planar reference facet in order to allow for an alignment or adjustment of the magnet with respect to another component, for example a sample. The reference facet may particularly be provided on the yoke or the pole tip and it may be parallel to a plane in which a sample shall be arranged.

In one embodiment, the attached pole tip may extend in line with the corresponding arm of the yoke. In another embodiment, the pole tip may extend perpendicular (preferred embodiment) or oblique to said arm.

According to a third aspect, an embodiment of the invention comprises a sensor apparatus with the following components:
An accommodation space for a sample.
A horseshoe magnet of the kind described above (i.e. with a yoke and a pole tip, wherein at least one arm of the yoke is attached to the pole tip and/or a cross-beam of the yoke but not integral with said pole tip and/or cross-beam, and with a coil) that is disposed adjacent to the aforementioned accommodation space.
Optics for guiding light towards the accommodation space and/or away from the accommodation space.

The accommodation space of the sensor apparatus may particularly be designed to accommodate a cartridge that houses a sample to be examined. Moreover, the optics is preferably designed to guide light through the space between the pole tips of the horseshoe magnet.

In a preferred embodiment, the optics of the sensor apparatus comprises a lens that is mounted between the pole tips of the horseshoe magnet. With the help of such a lens, it is possible to image a sample in the accommodation space without a need for space consuming components like a microscope objective.

According to a fourth aspect, an embodiment of the invention relates to a first method for the manufacturing of a horseshoe magnet. The method comprises the following steps that can be executed in the listed or any other appropriate order:
The production of a yoke with at least one arm.
The production of at least one pole tip.
The attachment of said pole tip to said arm of the yoke.

According to a fifth aspect, an embodiment of the invention relates to a second method for the manufacturing of a horseshoe magnet. The method comprises the following steps that can be executed in the listed or any other appropriate order:
The production of a cross-beam.
The production of at least one pole tip with an arm.
The attachment of said arm to the cross-beam.

The methods may particularly be applied to manufacture a horseshoe magnet of the kind described above. The methods and said horseshoe magnet are different realizations of the same inventive concept, i.e. the construction of a magnet assembly from a separate yoke and pole tip and/or a separate arm and cross-beam. Explanations and definitions provided for one of these realizations are therefore valid for the other realization, too.

The manufacturing methods may preferably further comprise the step of placing a wound coil on an arm of the yoke before the pole tip is attached to said arm (first method) and/or before the arm is attached to the cross-beam (second method). This has the advantage that winding of the coil can be done separately and without affecting the possibly sensitive components of the yoke and/or pole tip.

The separate production of the yoke and the pole tip and/or the cross-beam and the pole tip with an arm can be done by any appropriate method. In particular, the yoke, the cross-beam, and/or the pole tip (with or without arm) can be produced by
electro-discharge manufacturing (EDM);
machining;
metal injection molding;
additive manufacturing, for example electron beam melting (EBM), direct metal laser sintering (DMLS), selective laser melting (SLM), selective laser sintering (SLS), direct laser deposition (DLD), laser engineering net shapes (LENS), direct metal deposition (DMD), or laser metal deposition (LMD).

The separate parts (e.g. yoke and the pole tip) can optionally be manufactured by the same procedure. There is however also the opportunity to use different manufacturing technologies for these parts (e.g. for the yoke and for the pole tip(s)). Extra features can for example be included in the yoke such as rounded edges to avoid cutting of coil wires, resulting in a preference for e.g. metal injection molding, whereas the associated pole tips may be made e.g. by means of wire EDM for accuracy.

The invention further relates to the use of the horseshoe magnet and/or the sensor apparatus described above for molecular diagnostics, biological sample analysis, chemical sample analysis, food analysis, and/or forensic analysis. Molecular diagnostics may for example be accomplished with the help of magnetic beads or fluorescent particles that are directly or indirectly attached to target molecules.

### BRIEF DESCRIPTION OF THE DRAWINGS

These and other aspects of the invention will be apparent from and elucidated with reference to the embodiments described hereinafter.

In the drawings:

FIG. 1 shows a perspective view of a horseshoe magnet according to a first embodiment of the present invention;

FIG. 2 shows the yoke of the horseshoe magnet of FIG. 1 separately;

FIG. 3 shows a pole tip of the horseshoe magnet of FIG. 1 separately;

FIG. 4 shows a coil of the horseshoe magnet of FIG. 1 separately;

FIG. 5 shows a perspective view onto a cut through a sensor apparatus that comprises the horseshoe magnet of FIG. 1;

FIG. 6 shows a perspective view of a horseshoe magnet according to a second embodiment of the invention.

Like reference numbers or numbers differing by integer multiples of 100 refer in the Figures to identical or similar components.

### DETAILED DESCRIPTION OF EMBODIMENTS

The WO 2011/036634 A1 discloses a horseshoe magnet that accommodates a microscope objective lens for imaging magnetic beads in a cartridge. The gap between the pole tips needs to be rather wide to enable imaging with the microscope objective lens and for a sufficiently homogeneous magnetic field. To allow for the microscope objective lens, the magnet has a complex 3-dimensional shape. Also, the magnet is relatively large. The requirements of the magnetic field in the gap between the pole tips imply that the magnet has tight tolerances of the pole tip position and distance of about 20 μm.

The shape, size, tolerances and material make this magnet a relatively expensive component. The material is rare and thus expensive. The tolerances and the fact that in the manufacturing process the magnetic properties of the material should not be affected, imply that the conventional manufacturing method is electro-discharge manufacturing (EDM), which is an accurate but slow and thus expensive method. The size and shape of the component imply that the amount of base material is relatively large (about 2600 mm³ for a typical design of the magnet) and that a lot of this base material is wasted.

To address the above issues and to reduce the cost of a magnet that can be used in a biosensor, it is proposed to take one or more of the following measures:
Splitting of the magnet into several parts, e.g. two pole tips and a yoke, to reduce the amount of waste material.
Giving the pole tips and/or the yoke a two-dimensional shape for easy processing (e.g. with relatively simple EDM equipment).
Creating reference planes on the pole tips for accurate positioning of the pole gap with respect to a cartridge, resulting in a yoke with relatively large tolerances.
Allowing the production of the coils on a separated winding tool and placing them on the yoke when finished, thus not putting any stress on the highly-accurate magnet in the process of winding the coil.

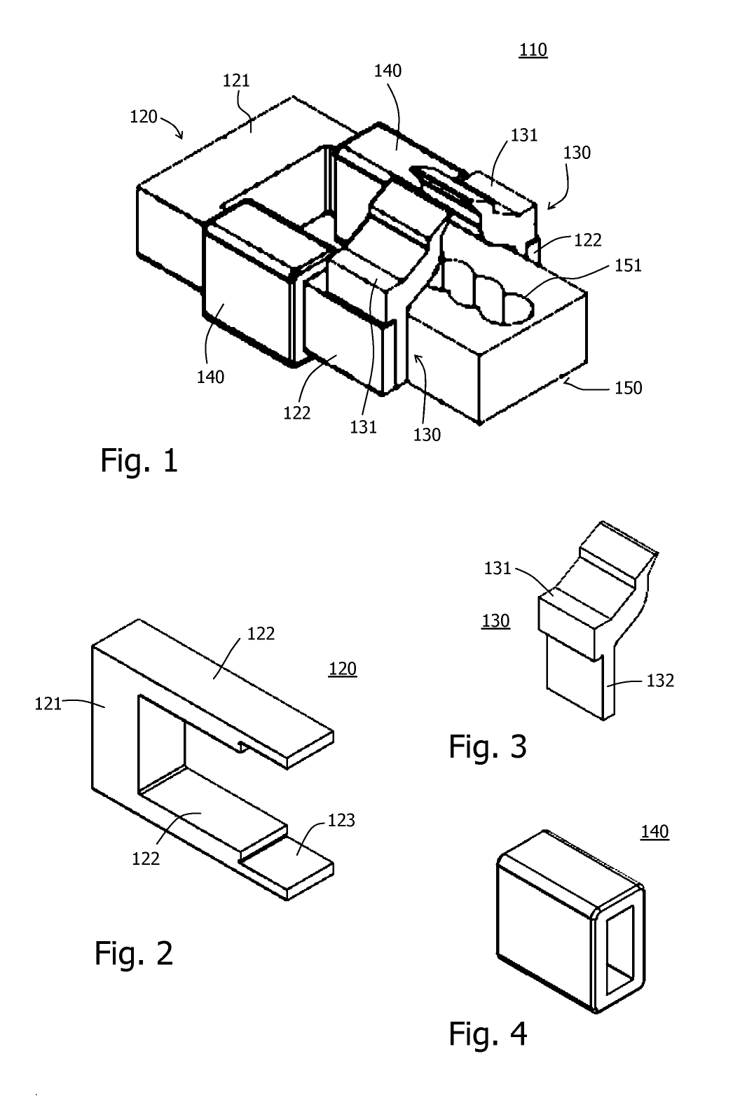

FIG. 1 schematically shows a horseshoe magnet 110 that is designed according to the above principles. The magnet comprises the following components:
A yoke 120 with two parallel arms 122 that are connected by a cross-beam 121. The distal ends of the arms 122 comprise a recess 123.
Two pole tips 130 that are attached in a mirror-symmetric fashion with legs 132 at the aforementioned recesses 123 to the arms 122. The pole tips 130 extend perpendicularly to the arms 122.
Two coils 140 that are positioned around the arms 122 of the yoke 120.

In the shown embodiment, the pole tips 130 are attached to the arms 122 of the yoke with the help of a mounting block 150 consisting of a non-magnetic material, for example of aluminum. The mounting block comprises central bores 151 for the passage of light. Both the yoke 120 and the pole tips 130 are preferably made from iron.

In comparison to a single-piece horseshoe magnet of similar size, the volume of raw material needed for the proposed magnet 110 is about 30% less.

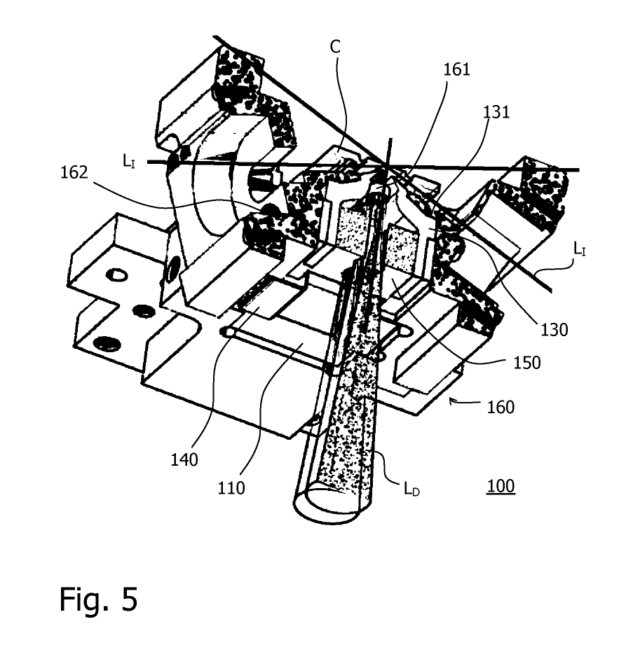

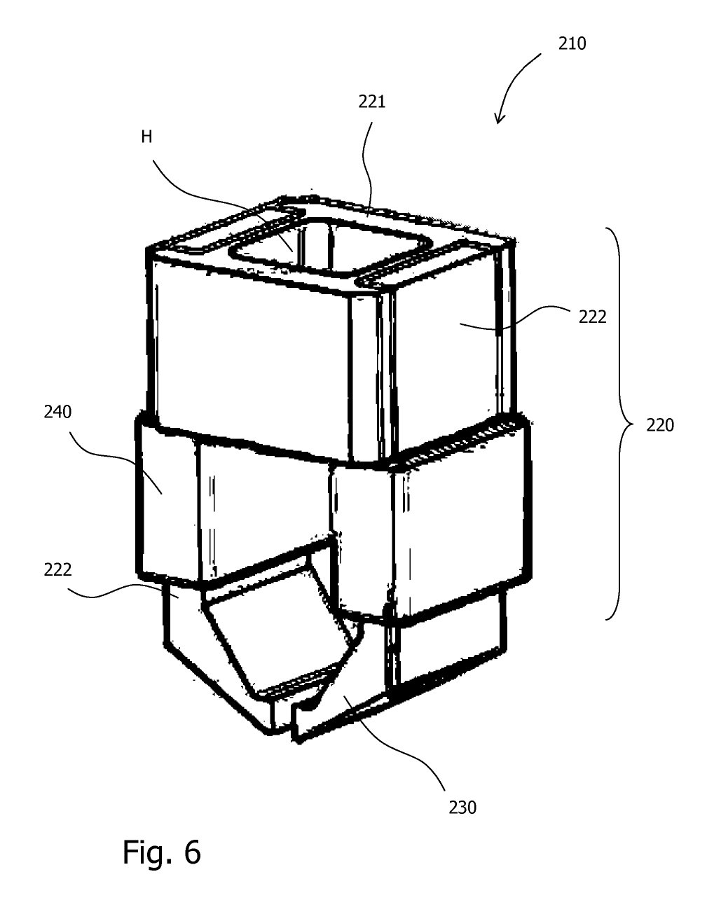

FIG. 5 shows how the horseshoe magnet 110 is mounted in a housing 160 of a system for single particle detection (biosensor apparatus 100). The apparatus 100 comprises an accommodation space in which an exchangeable cartridge C has been placed. Also shown are reference planes 131 of the pole tips 130, as well as a clamping screw 62 that clamps the pole tips to the yoke, with the help of the auxiliary mounting block 150. This auxiliary block is placed between the lower parts of the pole tips.

The proposed low-cost magnet 110 is preferably combined with small, single-lens imaging optics, replacing the need for a microscope objective lens. As shown, two or more such imaging lenses 161 are placed between the pole tips above the auxiliary mounting block 150. Light beams L_{I} for illuminating a region of interest in the cartridge C and light cones L_{D} with detection light for imaging said region are also illustrated. The small lenses 161 for imaging the magnetic beads allow for a reduction in size of the horseshoe magnet.

FIG. 5 shows a perspective view of a horseshoe magnet 210 according to a second embodiment of the invention. The magnet 210 comprises the following components:
A yoke 220 consisting of a cross-beam 221 and two arms 222.
Two pole tips 230 that are disposed at the ends of the arms 222 in a mirror symmetric fashion.

In contrast to the first embodiment, each pole tip 230 is here integrally formed with the associated arm 222, whereas the cross-beam 221 and the arms 222 are attached to each other but not integral (i.e. not one-piece). Moreover, the cross-beam 221 optionally comprises a hole H allowing access for optics such as a microscope objective or a lens (not shown). Embodiments without such a hole (but a massive cross-beam) are of course possible, too.

As in the first embodiment, the separate parts of the magnet 210 (i.e. the cross-beam 221 on the one hand side and the pole tips 230 with the integral arms 222 on the other hand side) have a cylindrical shape that can readily be manufactured. The cross-beam 221 can optionally be made of a material different from that of the pole tip(s)/arm(s) and/or be manufactured by a different method.

The described embodiments of the invention can be modified in a variety of ways, for example:
Both yoke and pole tips can be made of CoFe (a 50% cobalt 50% iron alloy) for maximum magnetic field strength, or the yoke can be made of Fe while the pole tips are made of CoFe, or the cross-beam can be made of Fe while the pole tips and the arms are made of CoFe etc.
The pole tips and the yoke (or the cross-beam and the arms) may be attached to each other by material bond, for example by gluing, so that the auxiliary block is no longer needed.
The pole tips and the yoke may be arranged in one line instead of being oriented at right angles, thus allowing for easy manufacturing and easy mounting of the coils.
The yoke and/or the pole tips (or the cross-beam and the pole tips with the arms) may be made by means of machining, by means of metal injection molding, and/or by means of additive manufacturing (like electron beam melting, direct metal laser sintering, selective laser melting, selective laser sintering, direct laser deposition, laser engineering net shapes, direct metal deposition, or laser metal deposition). They can be manufactured by the same or by different procedures.

In summary, embodiments of a low cost horseshoe magnet have been described that are made of three simple parts, for example an (e.g. iron) yoke and two (e.g. cobalt-iron) magnet tips. Cost reduction of this design is achieved by (1) use of inexpensive iron for the part of the horseshoe magnet where a large magnetic flux is not needed and the optional use of more expensive cobalt-iron only near the pole tips where a large magnetic field is required, (2) separation of the magnet into three parts to reduce material loss in production, and (3) referencing close to magnet tips to relax tolerances. The described magnets can for instance be applied to a magnetic biosensor, especially a magnetic biosensor for single particle detection.

While the invention has been illustrated and described in detail in the drawings and foregoing description, such illustration and description are to be considered illustrative or exemplary and not restrictive; the invention is not limited to the disclosed embodiments. Other variations to the disclosed embodiments can be understood and effected by those skilled in the art in practicing the claimed invention, from a study of the drawings, the disclosure, and the appended claims. In the claims, the word “comprising” does not exclude other elements or steps, and the indefinite article “a” or “an” does not exclude a plurality. A single processor or other unit may fulfill the functions of several items recited in the claims. The mere fact that certain measures are recited in mutually different dependent claims does not indicate that a combination of these measures cannot be used to advantage. Any reference signs in the claims should not be construed as limiting the scope.

1. A horseshoe magnet with two pole tips, particularly for a sensor apparatus, comprising:
a yoke with a cross-beam and at least one arm;
a pole tip that is attached to the arm of the yoke,
wherein the arm is not integral with said pole tip and/or not integral with the cross-beam;
at least one coil
characterized in that the coil fits over the arm when the pole tip is not attached to said arm and/or when the arm is not attached to the cross-beam .

2. The horseshoe magnet according to claim 1,
characterized in that said attached pole tip and the yoke consist of different materials, preferably of iron and an cobalt-iron alloy.

3. The horseshoe magnet according to claim 1,
characterized in that said attached pole tip is screwed on the yoke, clamped, particularly by means of a spring loaded arm, and/or attached by material bond.

4. The horseshoe magnet according to claim 1,
characterized in that a mounting block is disposed between two arms, of the yoke such that it presses the attached pole tip against the associated arm.

5. The horseshoe magnet according to claim 1,
characterized in that the yoke, its cross-beam, its arm, and/or the attached pole tip are cylindrical.

6. (canceled)

7. The horseshoe magnet according to claim 1,
characterized in that it comprises a lens that is mounted between two arms and/or the pole tips of the yoke.

8. The horseshoe magnet according to claim 1,
characterized in that it comprises a planar reference facet.

9. The horseshoe magnet according to claim 1,
characterized in that the attached pole tip extends in line with or perpendicular to or oblique to the arm.

10. A sensor apparatus, comprising
an accommodation space (C) for a sample;
a horseshoe magnet according to claim 1 that is disposed adjacent to the accommodation space;
optics for a guiding light (L) towards and/or away from the accommodation space.

11. The sensor apparatus according to claim 10,
characterized in that the optics comprises a lens that is mounted between the pole tips of the horseshoe magnet.

12. A method for manufacturing a horseshoe magnet said method comprising the following steps:
producing a yoke with at least one arm;
producing at least one pole tip;
attaching said pole tip to the arm of the yoke.

13. A method for manufacturing a horseshoe magnet, said method comprising the following steps:
producing a cross-beam;
producing at least one pole tip with an arm;
attaching said arm to the cross-beam.

14. The manufacturing method according to claim 12,
characterized in that the yoke, the cross-beam, and/or the pole tip is produced by a procedure selected from the group consisting of electro-discharge manufacturing, machining, metal injection molding, and additive manufacturing.

15. Use of the horseshoe magnet according to claim 1 and the sensor apparatus according to claim 10 for molecular diagnostics, biological sample analysis, chemical sample analysis, food analysis, and/or forensic analysis.
